(19) United States
(12) Patent Application Publication
(10) Pub. No.: US 2015/0084356 A1
(43) Pub. Date: Mar. 26, 2015

(54) Thumb-Free Finger Grip for Tablet Computers

(71) Applicants: HINH QUANG DINH, HOCHIMINH (VN); CHAU THI BAO DINH, SAN DIEGO, CA (US); HUY QUANG DINH, SAN DIEGO, CA (US); VINCENT DUC VU, VISTA, CA (US)

(72) Inventors: HINH QUANG DINH, HOCHIMINH (VN); CHAU THI BAO DINH, SAN DIEGO, CA (US); HUY QUANG DINH, SAN DIEGO, CA (US); VINCENT DUC VU, VISTA, CA (US)

(21) Appl. No.: 14/033,457

(22) Filed: Sep. 21, 2013

(51) Int. Cl. H05K 5/02

(52) U.S. Cl. CPC H05K 5/023
USPC 294/25

(57) ABSTRACT

Computer tablets require users to hold the device by one hand and perform other tasks with the other hand. It has been causing difficulty for people who have a need to use the tablet when they do not have both hands available to use the device. This invention has 3 different novel designs that enable three or less fingers to hold the tablet, leaving other fingers for other usages on the tablet.

| | | | |
|---|---|---|---|
| Inventor's Name: | DINH | HINH | QUANG |
| | (Last) | (First) | (Middle) |
| Applicant's Name: | DINH | HINH | QUANG |
| | (Last) | (First) | (Middle) |

Citizenship: Vietnamese
Residence: Vietnam

### CROSS-REFERENCE TO RELATED APPLICATIONS

Not Applicable

### BACKGROUND OF THE INVENTION

Tablets (herein refer to smartphones, tablet computers, ebook readers, etc . . . ) are being used more and more. However, those who have to use them for a while may find it uncomfortable, since they will have to hold continuously by one hand, and use the other hand to flip page, zoom, or move, etc . . .

There has been a need of an equipment to help users to hold the device and have at least 1 finger free from the holding task to operate the touch screen. The need is more obvious if the device has a screen size of about 18 centimeters (7 inches) or larger. Such tool has not been found in the marketplace.

### BRIEF SUMMARY OF THE INVENTION

This invention helps users to hold and control tablets using only one hand, with their thumb completely free from the holding task. The invention further makes possible such designs where holders can free not only the thumb but also the index finger of the user. Tablet holders made from this invention enable users to zoom, scroll up and down with their thumb and index finger while holding the tablets with the same hand just like using a smartphone. (See FIG. 1)

### BRIEF DESCRIPTION OF THE SEVERAL VIEWS OF THE DRAWING

FIG. 1—How a user holds a tablet with the Free Thumb grip.

FIG. 2—Tablet with back plate attached.

FIG. 3—Tube-like finger grip attached to back plate that is gripped to tablet.

FIG. 4A—Tube-like finger grip with 1 tube-like object attached.

FIG. 4B—Tube-like finger grip with 2 tube-like objects attached.

FIG. 4C—Tube-like finger grip with 3 tube-like objects attached.

FIG. 5—Removable tube-like finger grip.

FIG. 6—Rotatable tube-like finger grip.

FIG. 7A—Trumpet bell finger grip (overview).

FIG. 7B—Trumpet bell finger grip (side view).

FIG. 8—Big-top-small-bottom shape.

FIG. 9—Big-top-small-bottom shape works for various finger sizes. The smaller the

fingers, the closer they fit to the center of the grip.

FIG. 10A—Y-shaped finger grip attached to back plate that is gripped to tablet (upright position).

FIG. 10B—Y-shaped finger grip attached to back plate that is gripped to tablet (flat-folded position).

FIG. 11—How Y-shaped finger grip works for various finger sizes. The smaller the fingers, the closer they are to the center of the grip.

FIG. 12—Flat-folded Y-shaped finger grip.

FIG. 13—Rotatable Y-shaped finger grip allows the user to hold the tablet in portrait, landscape, or any direction.

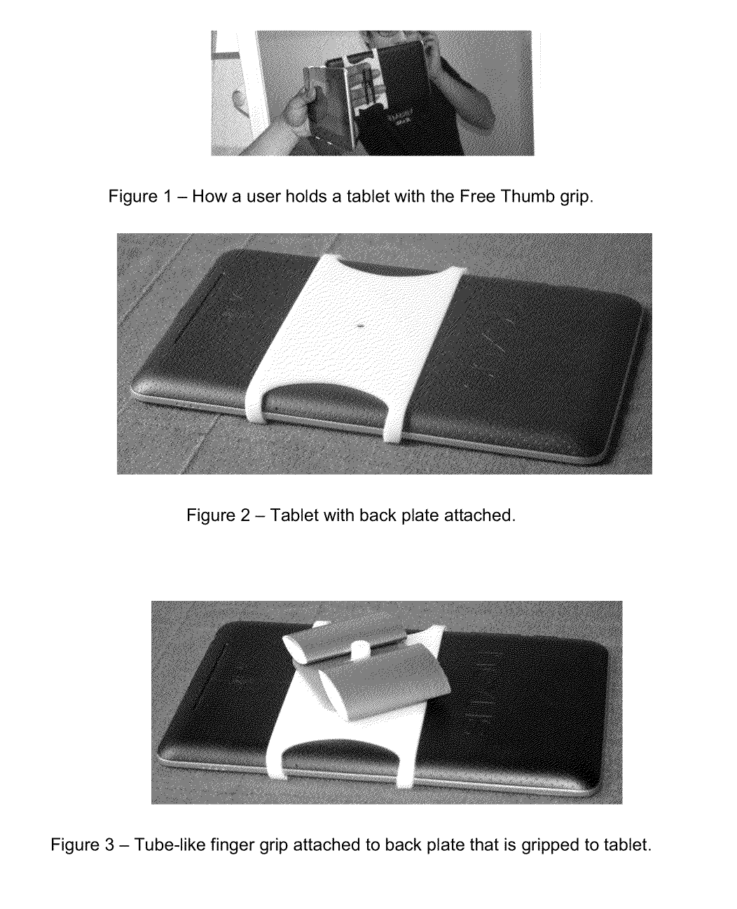

### DETAILED DESCRIPTIONS OF THE INVENTION

A tablet contains a screen. The back of tablet refers to the opposite side of the screen side.

A back plate is clipped or taped to the back of the tablet (See FIG. 2). A finger grip is defined as an object which tablet user's fingers grip on. In this invention, the finger grip can be attached onto the back plate or directly onto the back of tablet. The finger grip allows 3 or less fingers to hold the tablet. The invention proposes 3 different designs for the finger grip.

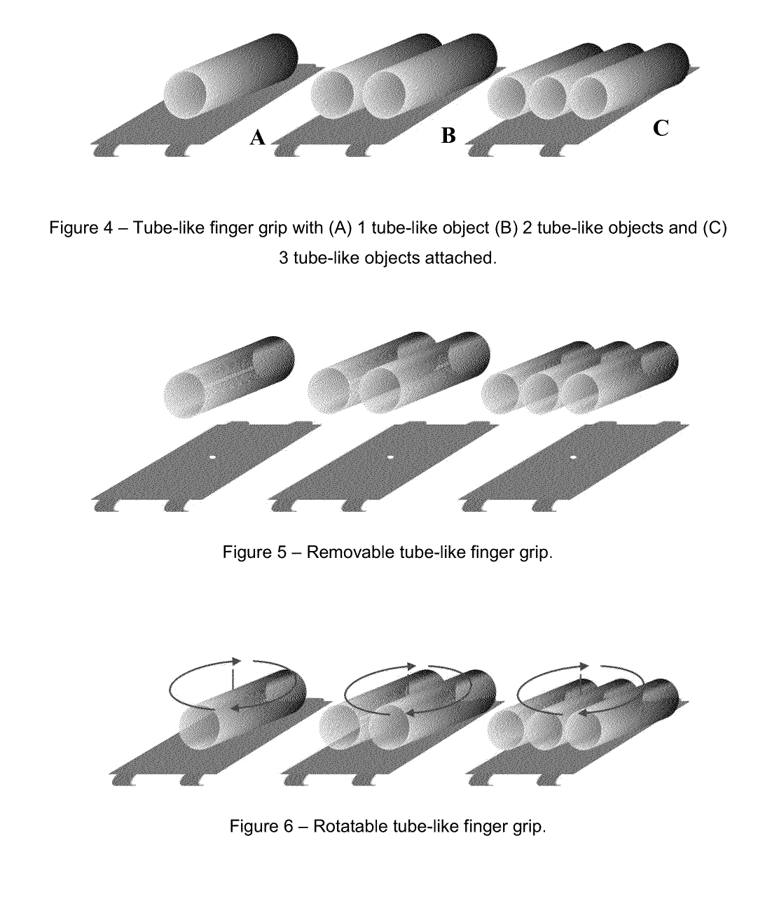

The first type is the tube-like finger grip. Users' fingers will insert into the tubes to hold the tablet. They are glued to a pivot plate to enable users to rotate the tablet around (See FIG. 3). A design of this type can have one (see FIG. 4A), two (see FIG. 4B), or three (see FIG. 4C) tube-like objects. When not in use, the finger grip makes the device unbalanced. Hence, it is desirable to make the finger grip removable (see FIG. 5). Furthermore, this invention also satisfies the need to hold the tablet in different orientations, such as portrait or landscape (see FIG. 6).

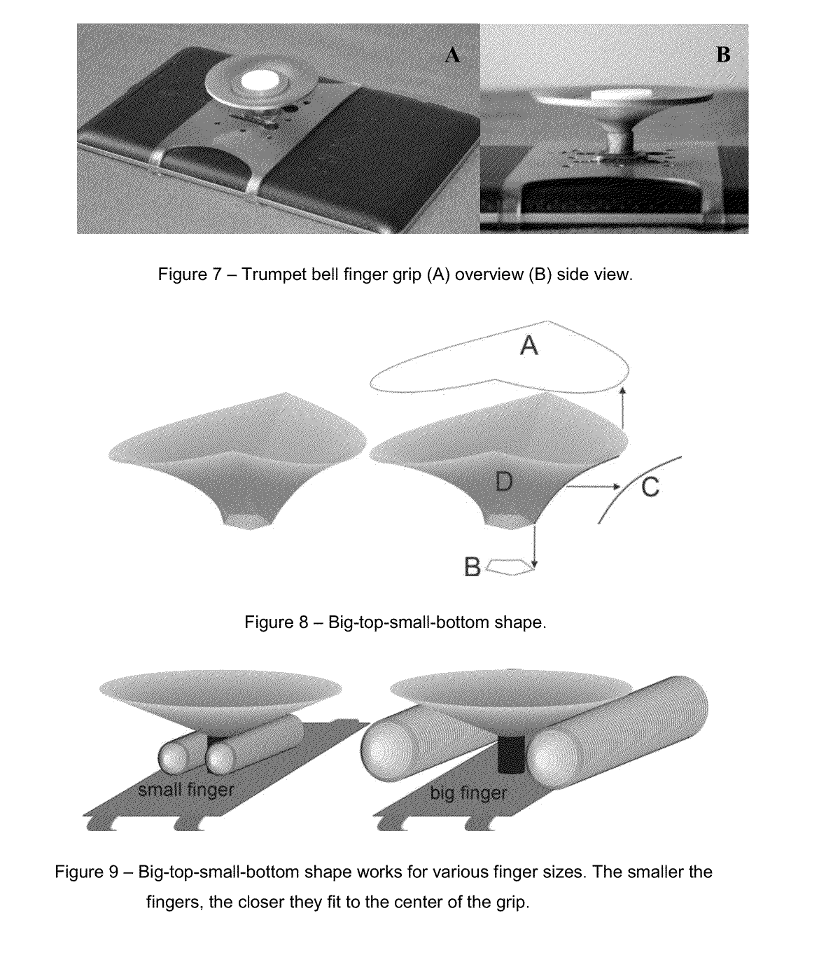

The second type is the big-top-small-bottom finger grip where two fingers can easily grip it to hold the tablet in all directions (see FIG. 7). Big-top-small-bottom shape is described as follows (see FIG. 8). A is the top part. B is the bottom part. A and B are closed curves of any shape where the dimensions of B are smaller than that of A. D is an infinite set of all the transitional shapes from A to B. The border of those transitional shapes is depicted by curve C. D depicts the shape of the big-top-small-bottom finger grip. This design has an advantage that it can be used by fingers of various sizes. The smaller the finger is, the closer it is to the center of the finger grip (see FIG. 9). For this design, the users can rotate the device in any direction without any addition rotation mechanism. It is also desirable to be removable. In the preferred mode of the second type, the big-top-small-bottom is a trumpet bell shape where curve C is concave toward the center of the grip (see FIGS. 7A, 7B and 8).

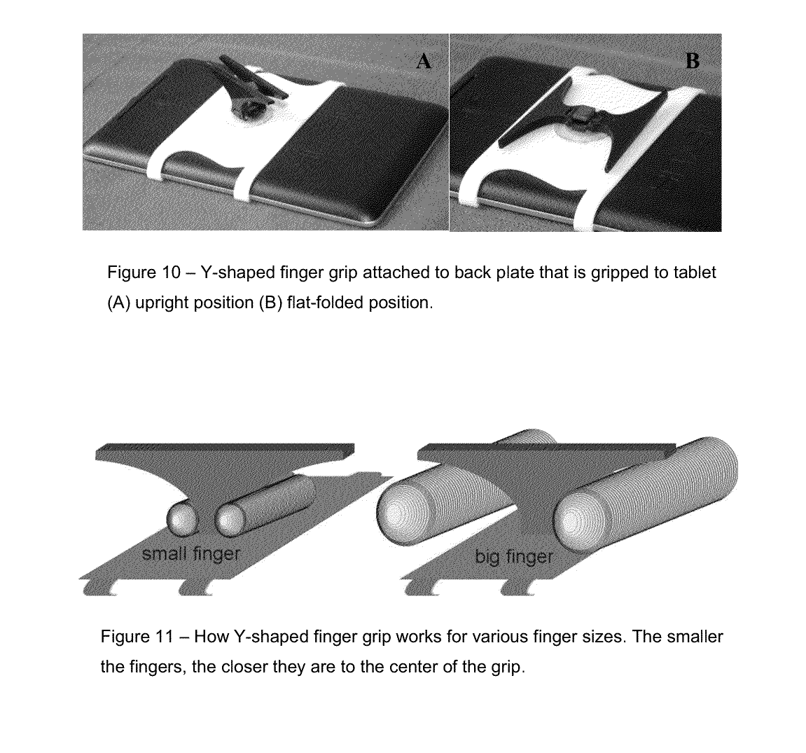

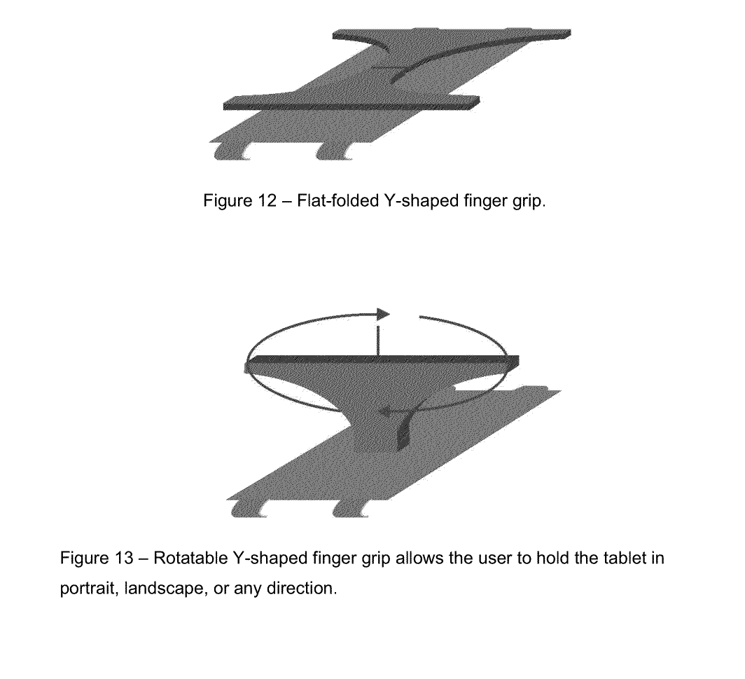

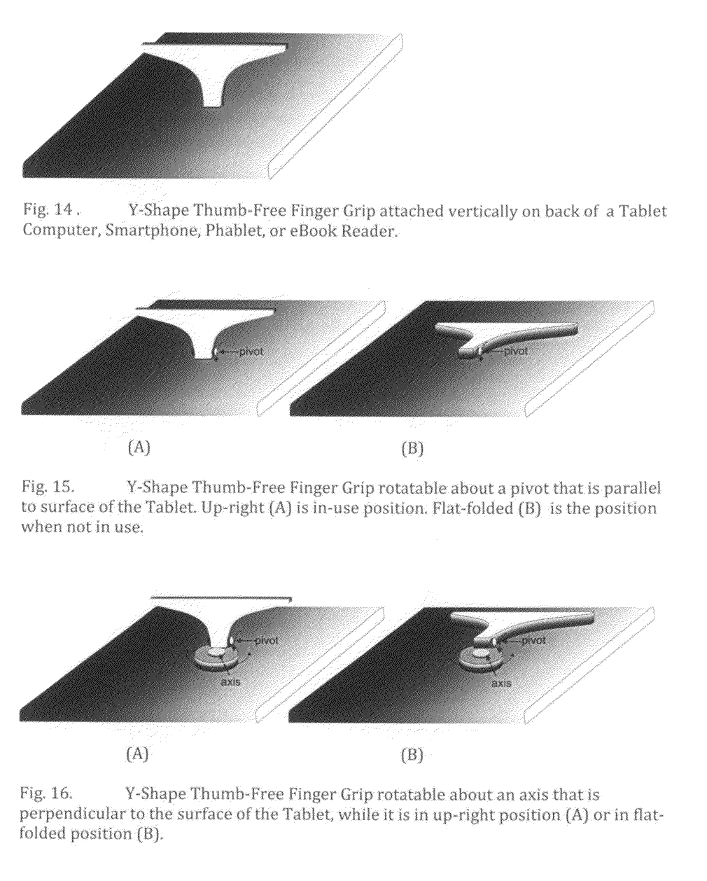

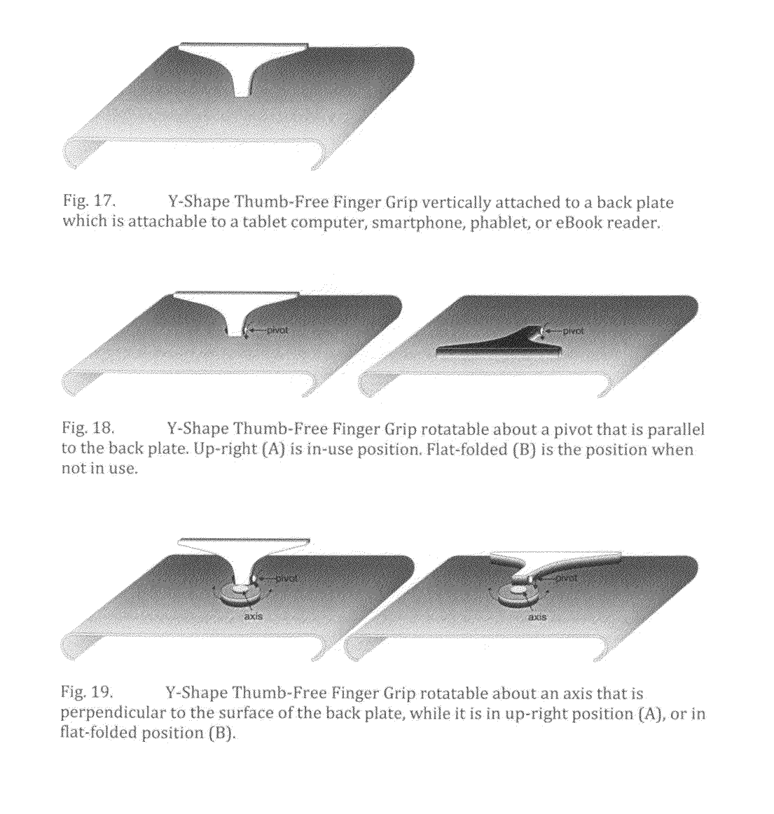

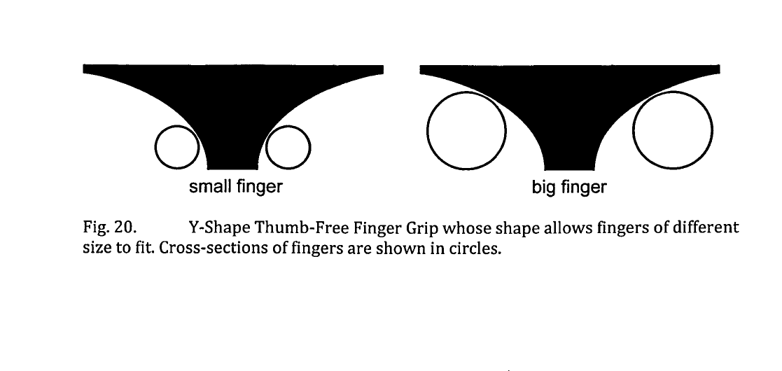

The third type is the Y-shaped finger grip (see FIG. 10). Y-shape is defined as the cross section through the rotational axis, which refers to the axis about which the finger grip rotates, of any of the big-top-small-bottom shape. Two fingers can easily hold the tablet. The smaller the finger is, the closer it is to the center of the grip (see FIG. 11). One advantage that the third type has over the second type is that it has one smaller dimension. Thus, this design allows the grip to be flat-folded when not in use (see FIGS. 10 and 12). In the preferred design, a rotation mechanism is implemented (see FIG. 13).

1. (canceled)

2. (canceled)

3. (canceled)

4. (canceled)

5. (canceled)

6. (canceled)

7. (canceled)

8. (canceled)

9. (canceled)

10. A thumb-free finger grip to allow a user of a tablet in the group comprised of tablet computers, smartphones, phablets, and eBook readers to hold and to operate such tablet at the same time using fingers of the same hand comprising:
at least a Y-shaped holder attachable to the back of such tablet vertically, wherein the shape of the holder allows different sizes of fingers to fit relatively comfortably.

11. A thumb-free finger grip of claim 10, wherein the Y-shaped holder is rotatable about a pivot that is parallel to the surface of the back of such table so that it can be flat-folded when not in use.

12. A thumb-free finger grip of claim 10, wherein the Y-shaped holder is rotatable about an axis that is perpendicular to the surface of the back of such tablet.

13. A thumb-free finger grip to allow a user of a tablet in the group comprised of tablet computers, smartphones, phablets, and eBook readers to hold and to operate such tablet at the same time using fingers of the same hand comprising:
a back plate attachable to the back of such tablet, and
at least a Y-shaped holder attachable to the back plate vertically, wherein the shape of the holder allows different sizes of fingers to fit relatively comfortably.

14. A thumb-free finger grip of claim 13, wherein the Y-shaped holder is rotatable about a pivot that is parallel to the surface of the back of such table so that it can be flat-folded when not in use.

15. A thumb-free finger grip of claim 13, wherein the Y-shaped holder is rotatable about an axis that is perpendicular to the surface of the back of such tablet.
